(19) United States
(12) Patent Application Publication
(10) Pub. No.: US 2011/0011452 A1
(43) Pub. Date: Jan. 20, 2011

(54) Concentration Photovotaic Apparatus

(75) Inventors: Kuo-Hsin LIN, Longtan Shiang (TW); Hwen-Fen Hong, Longtan Shiang (TW); Zun-Hao Shih, Longtan Shiang (TW); Yi-Ping Liang, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 12/253,981

(22) Filed: Oct. 19, 2008

(51) Int. Cl. H01L 31/0224

(52) U.S. Cl. 136/256

(57) ABSTRACT

A concentration photovoltaic apparatus includes a substrate, a bypass diode, a solar cell and an adhesion layer. The substrate includes five conduction regions. The solar cell is provided on the fourth conduction region, on a side of the cutouts, and connected to the third and fifth conduction regions through wires. The adhesion layer is provided between the solar cell and the fourth conduction region.

### FIELD OF THE INVENTION

The present invention relates to a concentration photovoltaic apparatus and, more particularly, to a concentration photovoltaic apparatus for ensuring firm connection of a solar cell to an external electric device and precise positioning of the solar cell on a substrate when the solar cell is soldered to the substrate.

### DESCRIPTION OF THE RELATED ARTS

Referring to FIG. 5, a typical photovoltaic apparatus includes a substrate 5 and a solar cell 6 provided on the substrate 5. The substrate 5 includes a first conduction region 51, a U-shaped conduction region 52 around the first conduction region 51 and an isolation region 53 between the first conduction region 51 and the second conduction region 52. Although not shown, an adhesion layer is provided between the solar cell 6 and the first conductive region 51. The photovoltaic apparatus can be connected to an external electric device 7 with wires 71. One of the wires 71 is connected to a contact 511 of the first conduction region 51. The other wire 71 is connected to a contact 521 of the second conduction region 52. Thus, the photovoltaic apparatus can convert solar energy into electricity for energizing the external electric apparatus 7.

There is a problem with the concentration photovoltaic apparatus. The contact 521 is very close to the solar cell 6 so that the connection of the contact 521 to the related wire 71 would be affected by the solar cell 6 which gets very hot in operation. In such a case, the supply of the electricity to the external electric apparatus 7 from the concentration photovoltaic apparatus would be interrupted.

The present invention is therefore intended to obviate or at least alleviate the problems encountered in prior art.

### SUMMARY OF THE INVENTION

It is an objective of the present invention to provide a concentration photovoltaic apparatus for ensuring firm connection of a solar cell to an external electric device.

It is another objective of the present invention to provide a concentration photovoltaic apparatus for ensuring precise positioning of a solar cell on a substrate when the solar cell is soldered to the substrate.

To achieve the foregoing objectives, the concentration photovoltaic apparatus includes a substrate, a bypass diode, a solar cell and an adhesion layer. The substrate includes five conduction regions. The first conduction region is separated from the second conduction region. The third conduction region is integrated with the first conduction region. The fourth conduction region includes two cutouts therein. The fourth conduction region is integrated with the second conduction region but separated from the third conduction region. The fifth conduction region is connected to the third conduction region through a connection region. The bypass diode is provided on the fourth conduction region and formed with pins connected to the fifth conduction region. The solar cell is provided on the fourth conduction region, on a side of the cutouts, and connected to the third and fifth conduction regions through wires. The adhesion layer is provided between the solar cell and the fourth conduction region.

Other objectives, advantages and features of the present invention will become apparent from the following description referring to the attached drawings.

### BRIEF DESCRIPTIONS OF THE DRAWINGS

The present invention will be described via the detailed illustration of embodiments referring to the drawings.

FIG. 1 is a perspective view of a concentration photovoltaic apparatus according to the preferred embodiment of the present invention.

FIG. 2 is a top view of the concentration photovoltaic apparatus shown in FIG. 1.

FIG. 3 is a cross-sectional view of the concentration photovoltaic apparatus shown in FIG. 1.

FIG. 4 is a perspective view of an external electric device connected to the concentration photovoltaic apparatus shown in FIG. 1.

FIG. 5 is a perspective view of a conventional concentration photovoltaic apparatus and an external electric device.

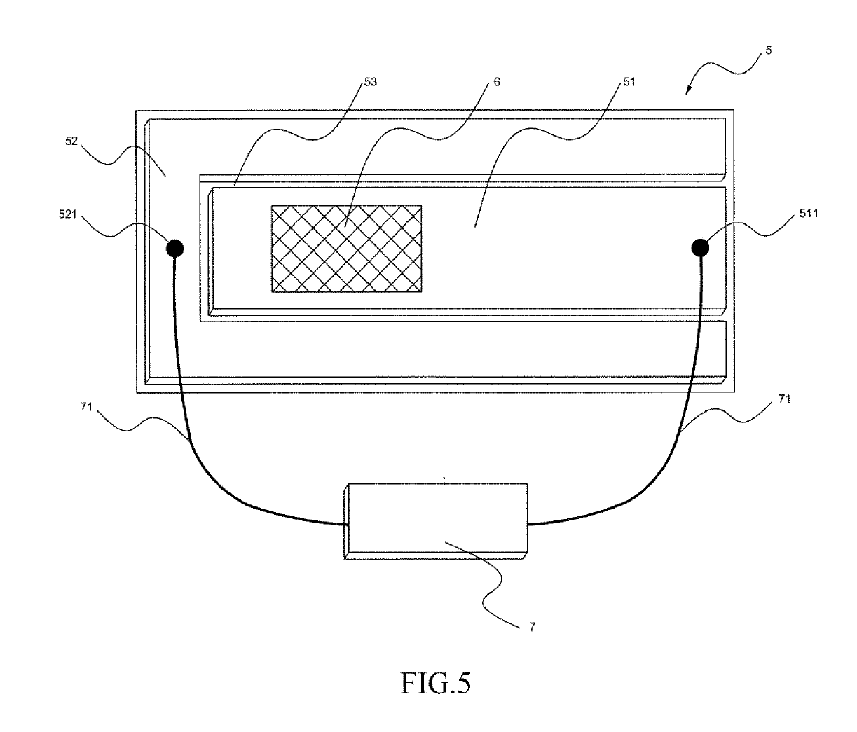

### DESCRIPTION OF THE PREFERRED EMBODIMENT

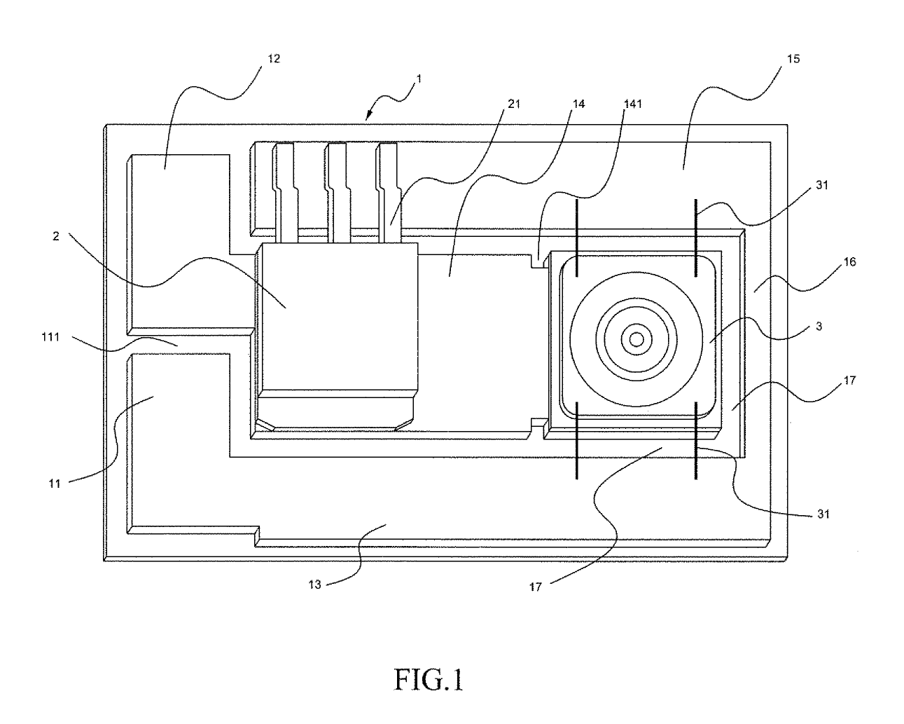

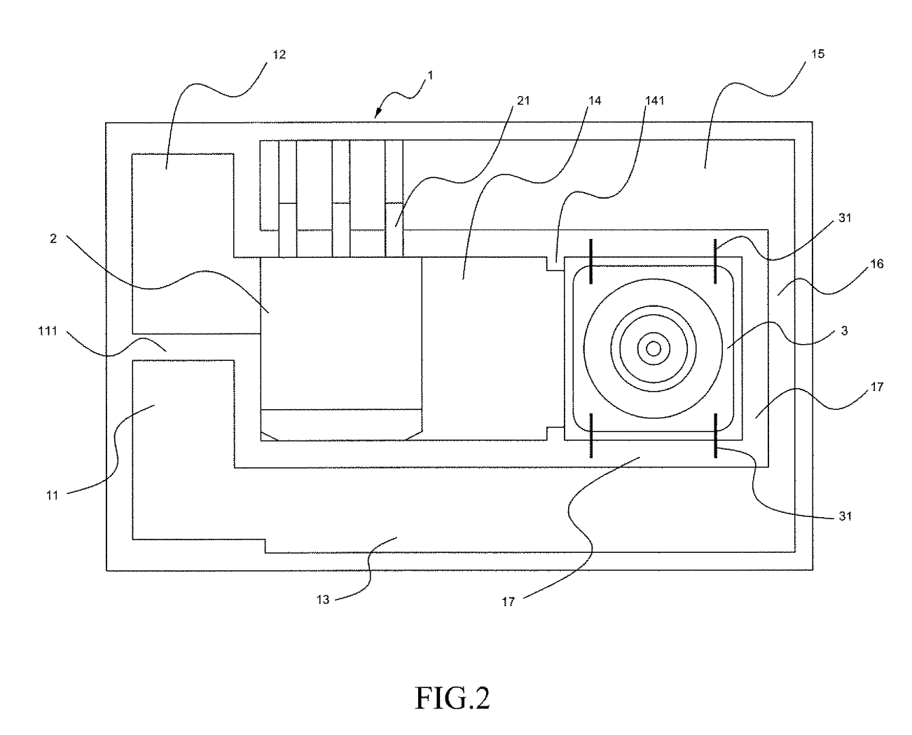

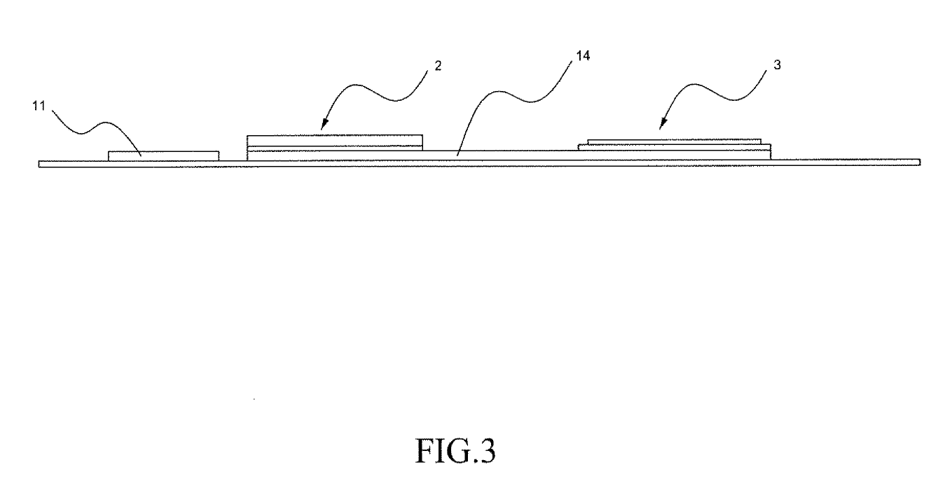

Referring to FIGS. 1 to 3, a concentration photovoltaic apparatus includes a substrate 1, a bypass diode 2 and a solar cell 3 according to the preferred embodiment of the present invention.

The substrate 1 includes first, second, third, fourth and fifth conduction regions 11 to 15. There is an isolation region 111 between the first and second conduction regions 11 and 12. The first conduction region 11 is integrated with the third conduction region 13. The second conduction region 12 is integrated with the fourth conduction region 14. There is a connection region 16 for connecting the third conduction region 13 to the fifth conduction region 15. There is an isolation region 17 for separating the third, fourth and fifth conduction regions 13, 14 and 15 from one another. There are two cutouts 141 defined in the fourth conduction region 14.

The bypass diode 2 is provided on the fourth conduction region 14 of the substrate 1. The bypass diode 2 includes pins 21 connected to the fifth conduction region 15.

The solar cell 3 is provided on the fourth conduction region 14, on a side of the cutouts 141. The solar cell 3 is connected to the third and fifth conduction regions through wires 31. There is an adhesion layer 32 between the solar cell 3 and the fourth conduction region 14. The adhesion layer 32 may be tin paste.

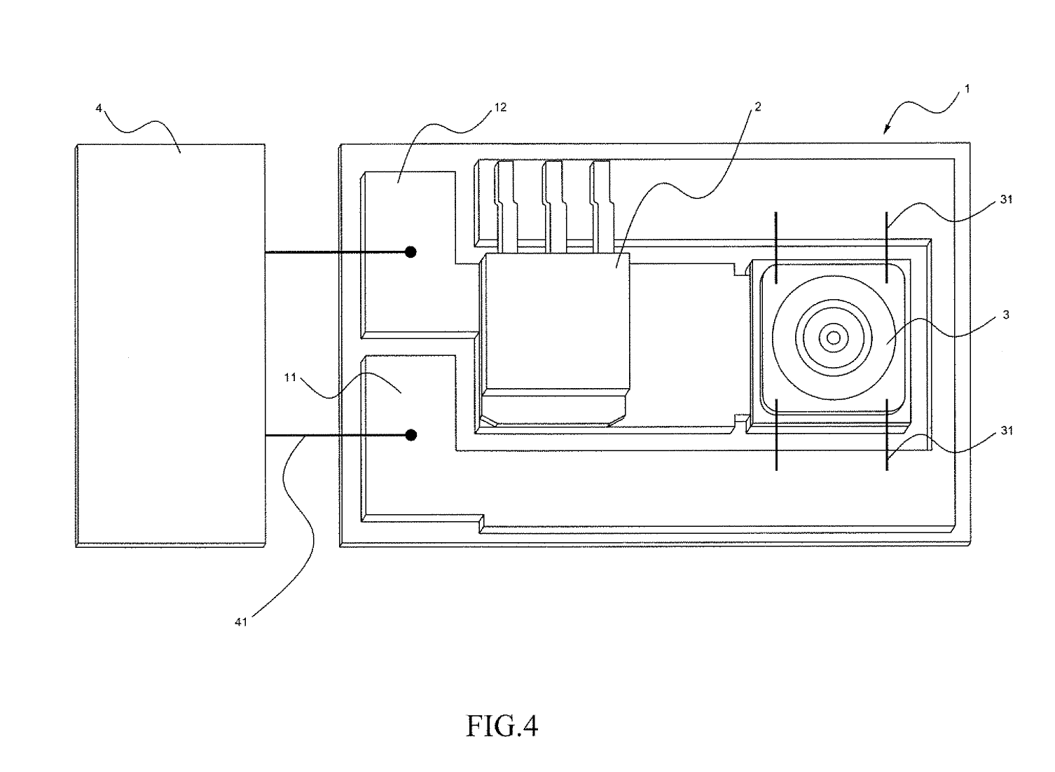

Referring to FIG. 4, an external electric device 4 is connected to the first and second conduction regions 11 and 12 through two wires 14. The contact points of the first and second conduction regions 11 and 12 with the wires 14 are located on another side of the cutouts 141. The solar cell 3 can convert solar energy to electricity for energizing the external electric apparatus 4. The bypass diode 2 provides a bypass circuit when the solar cell 3 stops. When the solar cell 3 is soldered to the fourth conduction region 14, the adhesion layer 32 is melted because of heat. The molten adhesion layer 32 tends to flow, and the solar cell 3 tends to drift on the molten adhesive layer 32. The cutouts 141 are useful in reducing the fluidity of the molten adhesive layer 32, thus reducing the drift of the solar cell 3 on the molten adhesion layer 32. That is, the solar cell 3 is properly positioned on the fourth conduction region 14. Moreover, the contact points of the first and second conduction regions 11 and 12 with the wires 14 are far from the solar cell 3 so that they are not vulnerable to heat generated by the solar cell 3 during operation. Therefore, the supply of the electricity to the external electric device 4 from the solar cell 3 is stable.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A concentration photovoltaic apparatus comprising:
a substrate comprising:
a first conduction region;
a second conduction region separated from the first conduction region;
a third conduction region integrated with the first conduction region;
a fourth conduction region formed with two cutouts, integrated with the second conduction region but separated from the third conduction region;
a fifth conduction region;
a connection region for connecting the fifth conduction region to the third conduction region;
a bypass diode provided on the fourth conduction region and formed with pins connected to the fifth conduction region;
a solar cell provided on the fourth conduction region, on a side of the cutouts, and connected to the third and fifth conduction regions through wires; and
an adhesion layer provided between the solar cell and the fourth conduction region.

2. The concentration photovoltaic apparatus according to claim 1, wherein the adhesion layer comprises tin paste.
